(19) United States
(12) Patent Application Publication
(10) Pub. No.: US 2024/0379564 A1
(43) Pub. Date: Nov. 14, 2024

(54) SEMICONDUCTOR STRUCTURE AND METHOD OF MAKING

(71) Applicant: Taiwan Semiconductor Manufacturing Company Limited, Hsin-Chu (TW)

(72) Inventors: Yi-Chu WU, New Taipei City (TW); Jen-Yuan CHANG, Hsinchu City (TW)

(21) Appl. No.: 18/196,070

(22) Filed: May 11, 2023

(51) Int. Cl. H01L 23/538; H01L 21/48; H01L 23/00; H01L 23/58; H01L 25/065

(52) U.S. Cl. CPC H01L 23/5383; H01L 21/4857; H01L 23/585; H01L 24/05; H01L 24/08; H01L 24/80; H01L 25/0655; H01L 23/3135; H01L 23/34; H01L 23/481; H01L 2224/05541; H01L 2224/05624; H01L 2224/05647; H01L 2224/05657; H01L 2224/05684; H01L 2224/08237; H01L 2224/80201; H01L 2224/80357; H01L 2224/80379; H01L 2224/80424; H01L 2224/80447; H01L 2224/80457; H01L 2224/80484; H01L 2224/80486; H01L 2224/80896; H01L 2924/05442; H01L 2924/059

(57) ABSTRACT

A method of forming a semiconductor structure includes forming a first conductive contact in a first dielectric layer coupled to a first device and forming a second conductive contact in the first dielectric layer coupled to a second device. A first trench is formed in the first dielectric layer having a first depth and exposing at least a portion of the first conductive contact. A second trench is formed in the first dielectric layer having a second depth different than the first depth and exposing at least a portion of the second conductive contact. A first conductive layer is formed in the first trench and the second trench. A second dielectric layer is formed in the first trench and the second trench over the first conductive layer.

### BACKGROUND

Stitching dies are used to interconnect multiple semiconductor dies to facilitate communication between the semiconductor dies.

### DESCRIPTION OF THE DRAWINGS

Aspects of the disclosure are understood from the following detailed description when read with the accompanying drawings. It will be appreciated that elements and/or structures of the drawings are not necessarily be drawn to scale. Accordingly, the dimensions of the various features may be arbitrarily increased and/or reduced for clarity of discussion.

FIGS. 1A-1C are illustrations of a semiconductor stitching structure at various stages of fabrication, in accordance with some embodiments.

FIG. 2 is a cross-section view illustrating a portion of a semiconductor structure, in accordance with some embodiments.

FIGS. 3A-3D illustrate a semiconductor package at various stages of fabrication, in accordance with some embodiments.

FIGS. 4A-4D illustrate a semiconductor package at various stages of fabrication, in accordance with some embodiments.

FIGS. 5A and 5B are top views of a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more techniques for forming a semiconductor structure and resulting structures formed thereby are provided herein. According to some embodiments, the present application relates to a semiconductor structure and a method for fabricating a semiconductor structure. According to some embodiments, a stitching die interconnects multiple semiconductor dies to facilitate communication between the semiconductor dies and to allow a vertical arrangement of semiconductor dies, such as stacked dies. In some embodiments, the stitching die comprises conductive structures formed in one or more dielectric layers. The one or more dielectric layers and conductive structures are formed above a substrate layer of a semiconductor layer. The substrate layer is removed to expose one of the one or more dielectric layers. The stitching die is bonded to underlying semiconductor dies using a hybrid bonding process, and a cooling structure is formed over the exposed dielectric layer of the stitching die. The removal of the substrate layer of the stitching die allows the cooling structure to be positioned closer to the underlying semiconductor dies, thereby increasing cooling efficiency and potentially increasing processing performance.

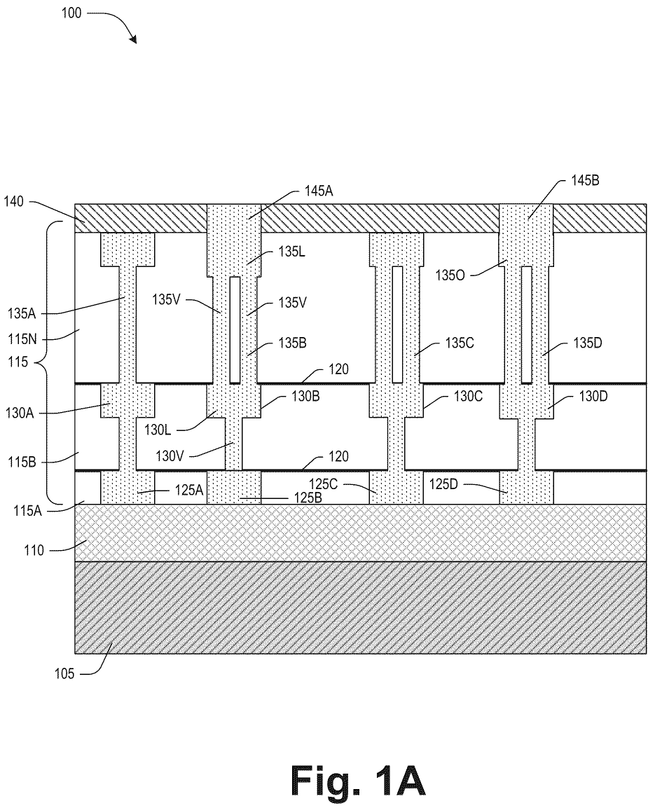

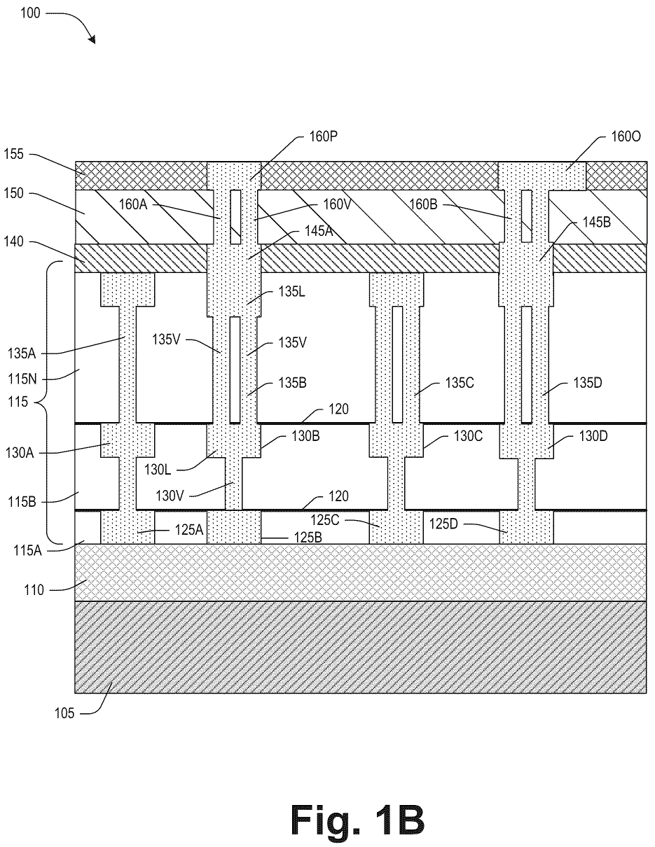

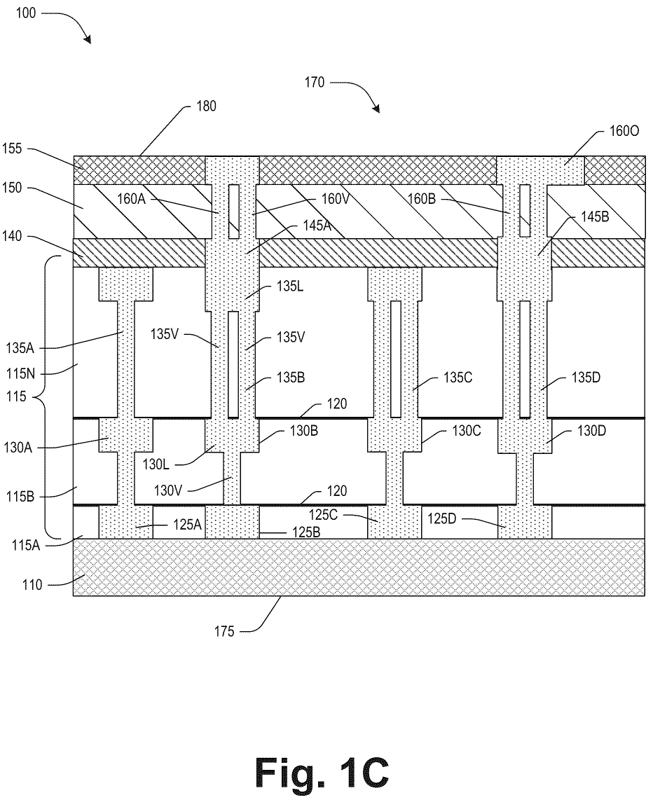

FIGS. 1A-1C illustrate a semiconductor stitching structure 100 at various stages of fabrication, in accordance with some embodiments. Referring to FIG. 1A, the semiconductor stitching structure 100 is formed on a substrate layer 105, in accordance with some embodiments. The substrate layer 105 comprises at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the substrate layer 105 comprises at least one of crystalline silicon or other suitable materials. Other structures and/or configurations of the substrate layer 105 are within the scope of the present disclosure.

In some embodiments, a base dielectric layer 110 is formed over the substrate layer 105. In some embodiments, the base dielectric layer 110 comprises silicon dioxide or a low-k dielectric material. In some embodiments, the base dielectric layer 110 comprises one or more layers of low-k dielectric material. Low-k dielectric materials have a k value lower than about 3.9. In some embodiments, the material for the base dielectric layer 110 comprise at least one of Si, O, C, or H, such as SiCOH, SiOC, oxygen-doped SiC (ODC), nitrogen-doped SiC (NDC), plasma-enhanced oxide (PEOX), or other suitable materials. A low-k dielectric material is, in some embodiments, further characterized or classified as ultra low-k (ULK), extra low-k (ELK), or extreme low-k (XLK), where the classification is generally based upon the k value. For example, ULK generally refers to materials with a k value of between about 2.7 to about 2.4, ELK generally refers to materials with a k value of between about 2.3 to about 2.0, and XLK generally refers to materials with a k value of less than about 2.0. Organic material, such as polymers, may be used for the base dielectric layer 110. In some embodiments, the base dielectric layer 110 comprises one or more layers of a carbon-containing material, organo-silicate glass, a porogen-containing material, or combinations thereof. The base dielectric layer 110 comprises nitrogen in some embodiments. In some embodiments, the base dielectric layer 110 is formed by using, for example, at least one of chemical vapor deposition (CVD), plasma-enhanced chemical vapor deposition (PECVD), low pressure CVD (LPCVD), atomic layer chemical vapor deposition (ALCVD), a spin-on technology, or some other suitable process.

In some embodiments, the semiconductor stitching structure 100 comprises one or more interlayer dielectric layers 115 formed over the base dielectric layer 110. According to some embodiments, the one or more interlayer dielectric layers 115 comprise a first interlayer dielectric layer 115A, a second interlayer dielectric layer 115B, and an N-th interlayer dielectric layer 115N. Any number of interlayer dielectric layers 115 are contemplated. One of the interlayer dielectric layers 115 may comprise a standard dielectric material with a medium or low dielectric constant, such as SiO₂. In some embodiments, at least one of the interlayer dielectric layers 115 comprises a dielectric material with a relatively low dielectric constant, as described for the base dielectric layer 110. The interlayer dielectric layers 115 are formed in any number of ways, such as by thermal growth, chemical growth, atomic layer deposition (ALD), CVD, PECVD, or some other suitable process. In some embodiments, one or more of the interlayer dielectric layers 115 in a lower portion comprise ULK or ELK dielectric materials, one or more of the interlayer dielectric layers 115 in an intermediate portion comprise low-k dielectric materials, and one or more of the interlayer dielectric layers 115 in an upper portion comprise standard-k dielectric materials, such as doped or undoped silicon glass.

In some embodiments, the semiconductor stitching structure 100 comprises one or more etch stop layers 120 separating the interlayer dielectric layers 115. In some embodiments, the etch stop layers 120 stop an etching process between the interlayer dielectric layers 115. According to some embodiments, the etch stop layers 120 comprise a dielectric material having a different etch selectivity from the interlayer dielectric layers 115. In some embodiments, at least one of the etch stop layers 120 comprises SiN, SiCN, SiCO, CN, etc., alone or in combination. The etch stop layers 120 are formed in any number of ways, such as by thermal growth, chemical growth, ALD, CVD, PECVD, or some other suitable process.

In some embodiments, the semiconductor stitching structure 100 comprises one or more conductive contacts 125A, 125B, 125C, 125D formed in the interlayer dielectric layer 115A. The conductive contacts 125A, 125B, 125C, 125D are formed in any number of ways, such as by a single damascene process, a dual damascene process, a trench silicide process, or some other suitable process. In some embodiments, the conductive contacts 125A, 125B, 125C, 125D comprise a barrier layer, a seed layer, a metal fill layer, or other suitable layers. The metal fill layer may comprise tungsten, aluminum, copper, cobalt, or other suitable material. Other structures and configurations of the conductive contacts 125A, 125B, 125C, 125D are within the scope of the present disclosure.

In some embodiments, the semiconductor stitching structure 100 comprises one or more conductive contacts 130A, 130B, 130C, 130D formed in the interlayer dielectric layer 115B. In some embodiments, the conductive contacts 130A, 130B, 130C, 130D extend through the interlayer dielectric layer 115B. In some embodiments, some of the conductive contacts 130A, 130B, 130C, 130D comprise a via portion 130V and a line portion 130L. The line portions 130L have an axial length extending into the page. In some embodiments, the conductive contacts 130A, 130B, 130C, 130D comprise a barrier layer, a seed layer, a metal fill layer, or other suitable layers. The metal fill layer may comprise tungsten, aluminum, copper, cobalt, or other suitable material. Other structures and configurations of the conductive contacts 130A, 130B, 130C, 130D are within the scope of the present disclosure.

In some embodiments, the semiconductor stitching structure 100 comprises one or more conductive contacts 135A, 135B, 135C, 135D formed in the interlayer dielectric layer 115N. In some embodiments, the conductive contacts 135A, 135B, 135C, 135D extend through the interlayer dielectric layer 115N. Some of the conductive contacts 135A, 135B, 135C, 135D may comprise via portions 135V and a line portion 135L. The line portions 135L have an axial length extending into the page. In some embodiments, the conductive contacts 135A, 135B, 135C, 135D comprise a barrier layer, a seed layer, a metal fill layer, or other suitable layers. The metal fill layer may comprise tungsten, aluminum, copper, cobalt, or other suitable material. Other structures and configurations of the conductive contacts 135A, 135B, 135C, 135D are within the scope of the present disclosure.

The conductive contacts 125A, 130A, 135A define a seal ring for the semiconductor stitching structure 100. The conductive contacts 125B, 130B, 135B and the conductive contacts 125D, 130D, 135D define conductive structures with external contacts, and the conductive contacts 125C, 130C, 135C define a conductive structure without an external contact.

In some embodiments, a passivation layer 140 is formed over the uppermost interlayer dielectric layer 115N. The passivation layer 140 may comprise one or more layers. In some embodiments, the passivation layer 140 comprises a polymer layer such as polyimide, benzocyclobutene (BCB), polybenzoxazole (PBO), an inorganic-organic hybrid material, such as ORMOCER®, or some other suitable passivation material. The passivation layer 140 serves as a mechanical protection and stress buffer layer. In some embodiments, a precursor of the passivation layer 140 is deposited by spin coating and/or other suitable techniques. Conductive contact pads 145A, 145B are formed in the passivation layer 140 to contact underling the conductive contacts 135A, 135C, respectively. In some embodiments, the conductive contact pads 145A, 145B comprise a barrier layer, a seed layer, a metal fill layer, or other suitable layers. The metal fill layer may comprise tungsten, aluminum, copper, cobalt, or other suitable material. The conductive contact pads 145A, 145B may be formed by forming recesses in the passivation layer 140, forming the material of the conductive contact pads 145A, 145B in the recesses, and performing a planarization process to remove portions of the material outside the recesses.

Referring to FIG. 1B, a dielectric layer 150 and a hybrid bonding layer 155 are formed over the passivation layer 140, and conductive contact pads 160A, 160B are formed in the dielectric layer 150 and the hybrid bonding layer 155, in accordance with some embodiments. In some embodiments, the dielectric layer 150 comprises a dielectric material with a relatively low dielectric constant, as described for the base dielectric layer 110. The dielectric layer 150 may be formed in any number of ways, such as by thermal growth, chemical growth, ALD, CVD, PECVD, or some other suitable process. In some embodiments, the hybrid bonding layer 155 comprises a standard-k dielectric material, such as silicon dioxide, doped or undoped silicon glass, SiON, or some other dielectric material. Some of the conductive contact pads 160A, 160B may comprise via portions 160V and contact pads 160P. In some embodiments, the conductive contact pads 160A, 160B comprise a barrier layer, a seed layer, a metal fill layer, or other suitable layers. The metal fill layer may comprise tungsten, aluminum, copper, cobalt, or other suitable material. One or more of the conductive contact pads 160A, 160B may comprise an offset structure 1600 that provides a lateral offset from the generally linear stack of conductive contacts in the conductive contact structures, such as the conductive contacts 125D, 130D, 135D, 145B. In some embodiments, the conductive contact pads 160A, 160B comprise a barrier layer, a seed layer, a metal fill layer, or other suitable layers. The metal fill layer may comprise tungsten, aluminum, copper, cobalt, or other suitable material. The conductive contact pads 160A, 160B may be formed by forming recesses in the dielectric layer 150 and the hybrid bonding layer 155, forming the material of the conductive contact pads 160A, 160B in the recesses, and performing a planarization process to remove portions of the material outside the recesses. Other structures and configurations of the conductive contact pads 160A, 160B are within the scope of the present disclosure.

Referring to FIG. 1C, the substrate layer 105 is removed, in accordance with some embodiments. In some embodiments, the semiconductor stitching structure 100 is inverted and a planarizing process is performed to remove the substrate layer 105. The planarization process may be terminated responsive to exposing the base dielectric layer 110 or after a predetermined time period. A semiconductor wafer comprising a plurality of semiconductor stitching structures 100 may be cut to provide a stitching die 170 having a first exposed surface 175 comprising a dielectric material, such as the base dielectric layer 110, and a second exposed surface 180 comprising a dielectric material, such as the hybrid bonding layer 155. In some embodiments, the stitching die 170 has a thickness of at least about 0.5 μm and includes at least two metallization layers to reduce the likelihood of stress induced cracking.

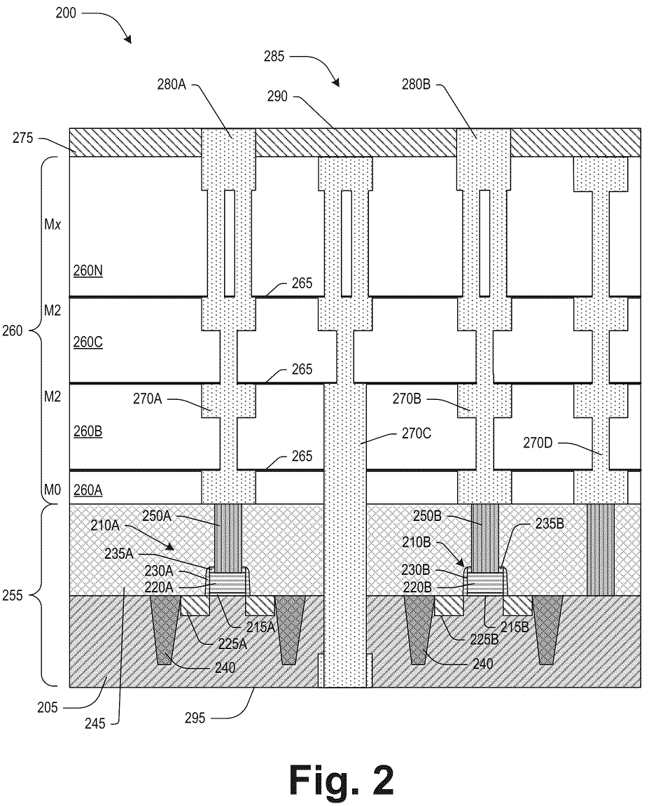

FIG. 2 is a cross-section view illustrating a portion of a semiconductor structure 200, in accordance with some embodiments. According to some embodiments, the semiconductor stitching structure 100 of FIG. 1C is used to interconnect two or more semiconductor dies created from the semiconductor structure 200 of FIG. 2. In an embodiment, the semiconductor structure 200 is formed on a substrate layer 205 comprising at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the substrate layer 205 comprises at least one of crystalline silicon or other suitable materials. Other structures and/or configurations of the substrate layer 205 are within the scope of the present disclosure.

According to some embodiments, the semiconductor structure 200 comprises a first device 210A and a second device 210B formed on or within the substrate layer 205. In some embodiments, the first device 210A and the second device 210B cach comprises a gate dielectric layer 215A, 215B, a gate electrode 220A, 220B, source/drain regions 225A, 225B, a sidewall spacer 230A, 230B, a gate cap layer 235A, 235B, etc. According to some embodiments, the gate dielectric layer 215A, 215B and the gate electrode 220A, 220B are formed using a gate replacement process. A sacrificial gate structure comprising a sacrificial gate dielectric layer, a sacrificial gate electrode layer, such as a polysilicon layer, and a hard mask layer are formed. In some embodiments, a patterning process is performed to pattern the hard mask layer corresponding to a pattern of gate structures to be formed, and an etch process is performed using the patterned hard mask layer to etch the sacrificial gate electrode layer and the sacrificial gate dielectric layer to define the sacrificial gate structure. In some embodiments, remaining portions of the hard mask layer form a cap layer over the portions of the sacrificial gate electrode layer remaining after the etch process. The sacrificial gate structure is later replaced with a replacement gate dielectric layer, such as the gate dielectric layer 215A, 215B and a replacement gate electrode, such as the gate electrode 220A, 220B.

In some embodiments, the gate dielectric layer 215A, 215B comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, AL2OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. In some embodiments, the gate electrode 220A, 220B comprises a barrier layer, one or more work function material layers, a seed layer, a metal fill layer, or other suitable layers. In some embodiments, the metal fill layer comprises tungsten, aluminum, copper, cobalt, or other suitable material. In some embodiments, the gate dielectric layer 215A, 215B and the one or more layers that comprise the gate electrode 220A, 220B are deposited by at least one of ALD, physical vapor deposition (PVD), CVD, LPCVD, ALCVD, ultrahigh vacuum CVD (UHVCVD), reduced pressure CVD (RPCVD), molecular beam epitaxy (MBE), or other suitable techniques. In some embodiments, the gate electrode 220A, 220B is recessed and the gate cap layer 235A, 235B is formed in the recess.

In some embodiments, the sidewall spacer 230A, 230B is formed adjacent the gate dielectric layer 215A, 215B and the gate electrode 220A, 220B. In some embodiments, the sidewall spacer 230A, 230B is formed by depositing a spacer layer over the sacrificial gate structure and performing an anisotropic etch process to remove horizontal portions of the spacer layer. In some embodiments, the sidewall spacer 230A, 230B comprises silicon nitride or other suitable materials.

In some embodiments, the source/drain regions 225A, 225B are formed in the substrate layer 205 after forming the sacrificial gate structure. For example, in some embodiments, portions of the substrate layer 205 are doped through an implantation process to form the source/drain regions 225A, 225B. In some embodiments, an etch process is performed to recess the substrate layer 205 adjacent the sidewall spacer 230A, 230B, and an epitaxial growth process is performed to form the source/drain regions 225A, 225B.

In an embodiment, one or more shallow trench isolation (STI) structures 240 are formed within the substrate layer 205. In some embodiments, the STI structures 240 are formed by forming at least one mask layer over the substrate layer 205. In some embodiments, the at least one mask layer comprises a layer of oxide material over the substrate layer 205 and a layer of nitride material over the layer of oxide material, and/or one or more other suitable layers. At least some of the at least one mask layer is removed to define an etch mask for use as a template to etch the substrate layer 205 to form trenches. A dielectric material is formed in the trenches to define the STI structure 240. In some embodiments, the STI structures 240 include multiple layers, such as an oxide liner, a nitride liner formed over the oxide liner, an oxide fill material formed over the nitride liner, and/or other suitable materials. Other structures and/or configurations of the STI structures 240 are within the scope of the present disclosure.

In some embodiments, the devices 210A, 210B are formed using the same materials and layer thicknesses. In some embodiments, different materials and/or thicknesses may be used due to the different voltage domains. For example, the material and/or thickness of the gate dielectric layers 215A, 215B may differ from one another. In some embodiments, the materials of the gate electrode 220A, 220B may also differ. Other structures and configurations of the devices 210A, 210B are within the scope of the present disclosure. For example, the devices 210A, 210B may be fin field-effect transistor (finFET) devices, nanosheet devices, nanowire devices, or some other suitable device.

In some embodiments, a dielectric layer 245 is formed over the devices 210A, 210B. In some embodiments, the dielectric layer 245 comprises silicon dioxide or a low-k dielectric material. In some embodiments, the dielectric layer 245 is formed by using, for example, at least one of CVD, PECVD, LPCVD, ALCVD, a spin-on technology, or some other suitable process.

In some embodiments, the semiconductor structure 200 comprises one or more conductive contacts 250A, 250B formed in the dielectric layer 245. The conductive contacts 250A, 250B are formed in any number of ways, such as by a single damascene process, a dual damascene process, a trench silicide process, or some other suitable process. In some embodiments, the conductive contacts 250A, 250B contact the gate electrodes 220A, 220B, and additional contacts (not shown) are formed to contact the source/drain regions 225A, 225B in different positions along the axial lengths of the devices 210A, 210B such as into or out of the page. In some embodiments, the conductive contacts 250A, 250B comprise a barrier layer, a seed layer, a metal fill layer, or other suitable layers. In some embodiments, the metal fill layer comprises tungsten, aluminum, copper, cobalt, or other suitable material. In some embodiments, the devices 210A, 210B, the conductive contacts 250A, 250B, and the dielectric layer 245 define a device layer 255 of the semiconductor structure 200. Other structures and configurations of the conductive contacts 250A, 250B are within the scope of the present disclosure.

In some embodiments, the semiconductor structure 200 comprises one or more dielectric layers 260 formed over the device layer 255. According to some embodiments, the one or more dielectric layers 260 comprise a second dielectric layer 260A, a third dielectric layer 260B, a fourth dielectric layer 260C, and an n-th dielectric layer 260N. Any number of dielectric layers 260 are contemplated. In some embodiments, at least one of the dielectric layers 260 comprises a standard dielectric material with a medium or low dielectric constant, such as SiO₂. In some embodiments, at least one of the dielectric layers 260 comprises a dielectric material with a relatively low dielectric constant, as described for the dielectric layer 245. The dielectric layers 260 are formed in any number of ways, such as by thermal growth, chemical growth, ALD, CVD, PECVD, or some other suitable process. In some embodiments, one or more of the dielectric layers 260 in a lower portion comprise ULK or ELK dielectric materials, one or more of the dielectric layers 260 in an intermediate portion comprise low-k dielectric materials, and one or more of the dielectric layers 260 in an upper portion comprise standard-k dielectric materials, such as doped or undoped silicon glass.

In some embodiments, the semiconductor structure 200 comprises one or more etch stop layers 265 separating the dielectric layers 260. In some embodiments, the etch stop layers 265 stop an etching process between the dielectric layers 260. According to some embodiments, the etch stop layers 265 comprise a dielectric material having a different etch selectivity from the dielectric layers 260. In some embodiments, at least one of the etch stop layers 265 comprises SiN, SiCN, SiCO, CN, etc., alone or in combination. The etch stop layers 265 are formed in any number of ways, such as by thermal growth, chemical growth, ALD, CVD, PECVD, or some other suitable process.

In some embodiments, the semiconductor structure 200 comprises one or more conductive structures 270A, 270B, 270C, 270D. The conductive structures 270A, 270B, 270C, 270D may be formed using similar techniques described above in reference to FIG. 1A. In some embodiments, the conductive structures 270A, 270B, 270C, 270D extend through their respective dielectric layers 260. The combination of a particular dielectric layer 260 and the associated portion of the conductive structures 270A, 270B, 270C, 270D in the particular dielectric layer 260 define a metallization layer, such as metallization layers “M0,” “M1,” “M2”, and “Mx.” The conductive structures 270A, 270B are structures for contacting the underlying devices 210A, 210B, respectively. The conductive structure 270C is a through silicon via (TSV) for contacting an underlying die when multiple die are stacked. The conductive structure 270D is a seal ring for the semiconductor structure 200.

In some embodiments, a passivation layer 275 is formed over the uppermost dielectric layer 260N. The passivation layer 275 may comprise one or more layers. In some embodiments, the passivation layer 275 comprises a polymer layer such as polyimide, BCB, PBO, an inorganic-organic hybrid material, such as ORMOCER®, or some other suitable passivation material. The passivation layer 275 serves as a mechanical protection and stress buffer layer. In some embodiments, a precursor of the passivation layer 275 is deposited by spin coating and/or other suitable techniques. Conductive contact pads 280A, 280B are formed in the passivation layer 275 to contact underling the conductive structures 270A, 270B, respectively. In some embodiments, the conductive contact pads 280A, 280B comprise a barrier layer, a seed layer, a metal fill layer, or other suitable layers. The metal fill layer may comprise tungsten, aluminum, copper, cobalt, or other suitable material. The conductive contact pads 280A, 280B may be formed by forming recesses in the passivation layer 275, forming the material of the conductive contact pads 280A, 280B in the recesses, and performing a planarization process to remove portions of the material outside the recesses. A semiconductor wafer comprising a plurality of semiconductor structures 200 may be cut to provide a semiconductor die 285 having a top surface 290 and a back surface 295.

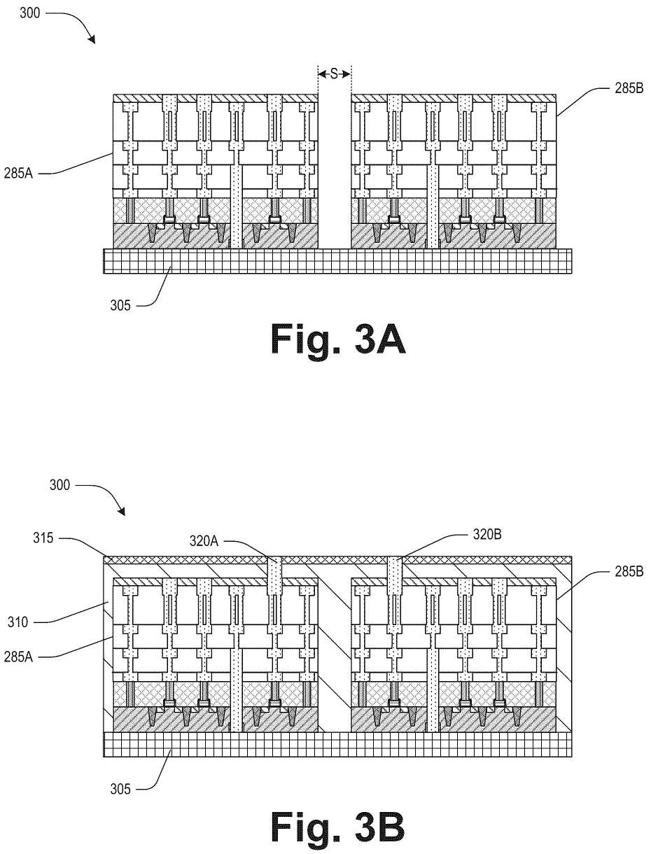

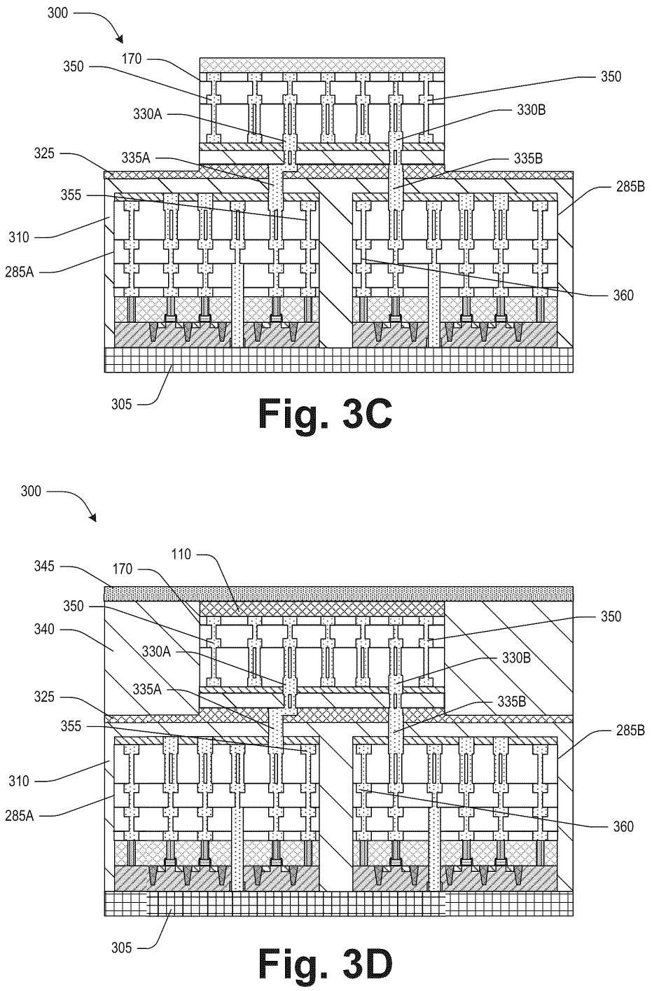

FIGS. 3A-3D illustrate a semiconductor package 300 at various stages of fabrication, in accordance with some embodiments. Referring to FIG. 3A, a first semiconductor die 285A and a second semiconductor die 285B are mounted to a base 305 in a top side up configuration, in accordance with some embodiments. For case of illustration, the reference numbers of FIG. 2 are not duplicated. In some embodiments, the base 305 includes one or more additional semiconductor die arranged in a stack, where the first semiconductor die 285A and the second semiconductor die 285B represent the top semiconductor dies in the stack. In some embodiments, the base 305 is a circuit board or an interposer. The base 305 may be a bonding layer, such as SiO₂ or SiON, to which the first semiconductor die 285A and the second semiconductor die 285B are bonded using a process that applies pressure and heat to facilitate the bonding. In an embodiment where a bonding process is used, a bonding layer may also be formed on the first semiconductor die 285A and the second semiconductor die 285B, for example, prior to the semiconductor structure 200 being singulated. In some embodiments, the first semiconductor die 285A and the second semiconductor die 285B are mounted to the base 305 by solder balls or other mounting arrangements. In some embodiments, a spacing S between the first semiconductor die 285A and the second semiconductor die 285B is at least 1.5 μm to allow for PnP variation.

Referring to FIG. 3B, a dielectric layer 310 and a hybrid bonding layer 315 are formed over the first semiconductor die 285A and the second semiconductor die 285B, and conductive contact pads 320A, 320B are formed in the dielectric layer 310 and the hybrid bonding layer 315, in accordance with some embodiments. In some embodiments, the dielectric layer 310 comprises a dielectric material with a relatively low dielectric constant, as described for the base dielectric layer 110, silicon dioxide, a molding compound, or some other dielectric material. The dielectric layer 310 may be formed in any number of ways, such as by thermal growth, chemical growth, ALD, CVD, PECVD, or some other suitable process. In some embodiments, the hybrid bonding layer 315 comprises a standard-k dielectric material, such as silicon dioxide, doped or undoped silicon glass, SiON, or some other dielectric material. The conductive contact pads 320A, 320B may comprise a barrier layer, a seed layer, a metal fill layer, or other suitable layers. The metal fill layer may comprise tungsten, aluminum, copper, cobalt, or other suitable material.

Referring to FIG. 3C, the stitching die 170 is bonded to the first semiconductor die 285A and the second semiconductor die 285B, in accordance with some embodiments. A bonding process that applies heat and pressure to the stitching die 170, the first semiconductor die 285A, and the second semiconductor die 285B causes bonding between the hybrid bonding layer 155 of the stitching die 170 and the hybrid bonding layer 315 to form a bonding layer 325 and bonding between conductive structures 330A, 330B in the stitching die 170 and conductive structures 335A, 335B in the first semiconductor die 285A and the second semiconductor die 285B. The number of conductive structures interconnecting the stitching die 170 with the first semiconductor die 285A and the second semiconductor die 285B may vary. The stitching die 170 facilitates communication between the first semiconductor die 285A and the second semiconductor die 285B. In some embodiments, the conductive structures 335A, 335B may be used as alignment guides for the placement of the stitching die 170. In some embodiments, the stitching die 170 is designed such that seal ring 350 of the stitching die 170 is spaced at least 0.5 μm from seal rings 355, 360 of the first semiconductor die 285A and the second semiconductor die 285B to avoid stacking of the seal rings 350, 355, 360.

Referring to FIG. 3D, a dielectric layer 340 and a cooling structure 345 are formed over the stitching die 170, the first semiconductor die 285A, and the second semiconductor die 285B, in accordance with some embodiments. In some embodiments, the dielectric layer 340 comprises a dielectric material with a relatively low dielectric constant, as described for the base dielectric layer 110, silicon dioxide, a molding compound, or some other dielectric material. The dielectric layer 340 may be formed in any number of ways, such as by thermal growth, chemical growth, ALD, CVD, PECVD, or some other suitable process. In some embodiments, the cooling structure 345 comprises a metal layer, a heat sink, a radiator structure, a base of a cooling fan, or some other cooling structure. In some embodiments, the removal of the substrate layer 105 from the semiconductor stitching structure 100 facilitates the cooling structure 345 being positioned closer to the first semiconductor die 285A and the second semiconductor die 285B. In some embodiments, the cooling structure 345 directly contacts the base dielectric layer 110 on the exposed surface 175 of the stitching die 170.

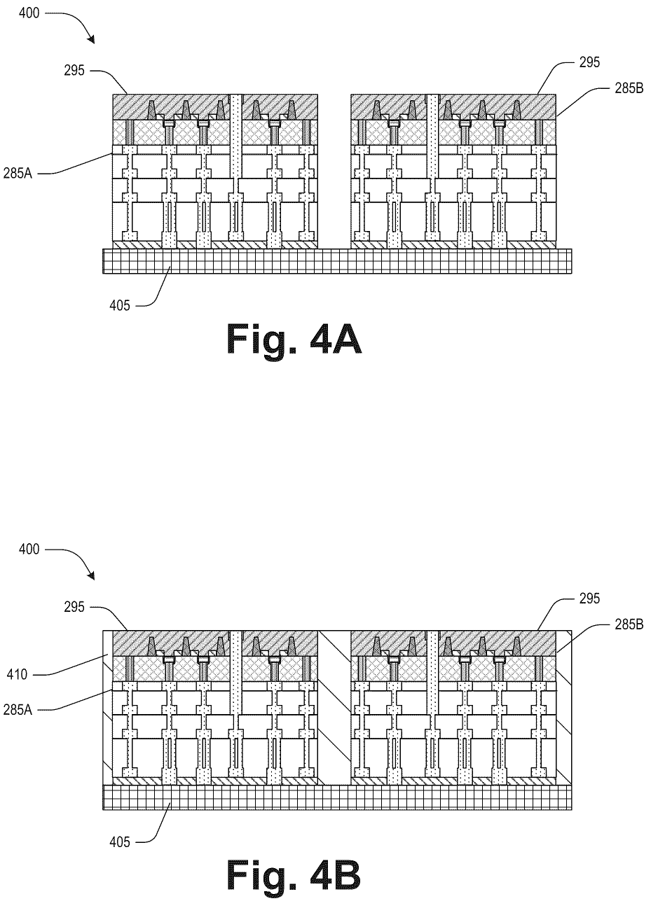

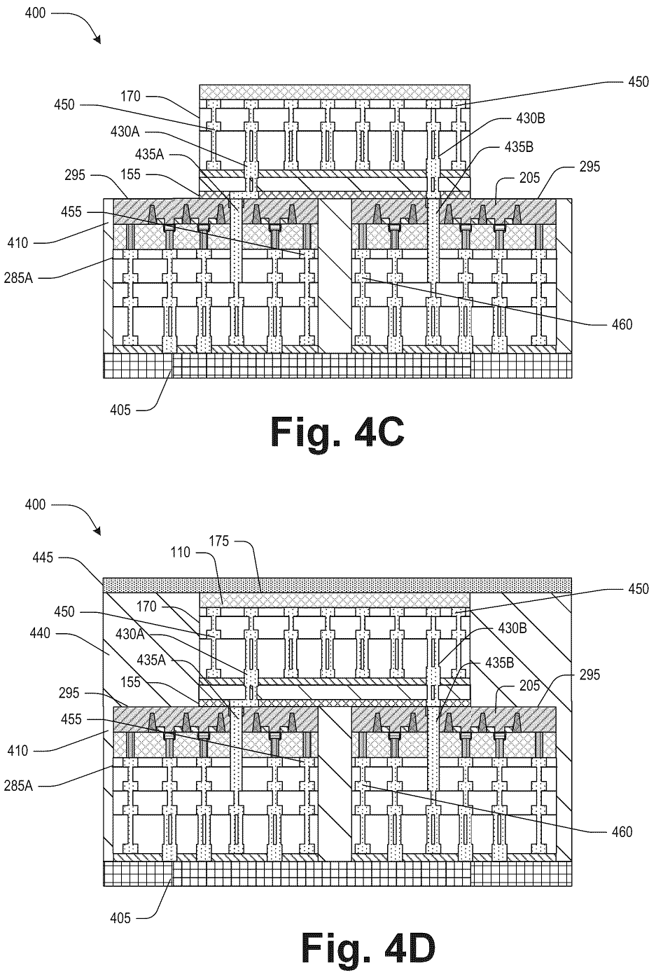

FIGS. 4A-4D illustrate a semiconductor package 400 at various stages of fabrication, in accordance with some embodiments. Referring to FIG. 4A, the first semiconductor die 285A and the second semiconductor die 285B are mounted to a base 405 in a back side up arrangement, in accordance with some embodiments. For ease of illustration, the reference numbers of FIG. 2 are not duplicated. The first semiconductor die 285A and the second semiconductor die 285B are oriented such that the back surface 295 is facing up.

Referring to FIG. 4B, a dielectric layer 410 is formed over the first semiconductor die 285A and the second semiconductor die 285B, in accordance with some embodiments. In some embodiments, the dielectric layer 410 comprises a dielectric material with a relatively low dielectric constant, as described for the base dielectric layer 110, silicon dioxide, a molding compound, or some other dielectric material. The dielectric layer 410 may be formed in any number of ways, such as by thermal growth, chemical growth, ALD, CVD, PECVD, or some other suitable process.

Referring to FIG. 4C, the stitching die 170 is bonded to the first semiconductor die 285A and the second semiconductor die 285B, in accordance with some embodiments. A bonding process that applies heat and pressure to the stitching die 170, the first semiconductor die 285A, and the second semiconductor die 285B causes bonding between the hybrid bonding layer 155 of the stitching die 170 and the substrate layer 205 of the first semiconductor die 285A and the second semiconductor die 285B and bonding between conductive structures 430A, 430B in the stitching die 170 and conductive structures 435A, 435B in the first semiconductor die 285A and the second semiconductor die 285B. The number of conductive structures interconnecting the stitching die 170 with the first semiconductor die 285A and the second semiconductor die 285B may vary. In some embodiments, the conductive structures 435A, 435B may be used as alignment guides for the placement of the stitching die 170. The stitching die 170 facilitates communication between the first semiconductor die 285A and the second semiconductor die 285B. In some embodiments, the stitching die 170 is designed such that scal ring 450 of the stitching die 170 is spaced at least 0.5 μm from seal rings 455, 460 of the first semiconductor die 285A and the second semiconductor die 285B to avoid stacking of the scal rings 450, 455, 460.

Referring to FIG. 4D, a dielectric layer 440 and a cooling structure 445 are formed over the stitching die 170, the first semiconductor die 285A, and the second semiconductor die 285B, in accordance with some embodiments. In some embodiments, the dielectric layer 440 comprises a dielectric material with a relatively low dielectric constant, as described for the base dielectric layer 110, silicon dioxide, a molding compound, or some other dielectric material. The dielectric layer 440 may be formed in any number of ways, such as by thermal growth, chemical growth, ALD, CVD, PECVD, or some other suitable process. In some embodiments, the cooling structure 445 comprises a metal layer, a heat sink, a radiator structure, a base of a cooling fan, or some other cooling structure. In some embodiments, the removal of the substrate layer 105 from the semiconductor stitching structure 100 facilitates the cooling structure 445 being positioned closer to the first semiconductor die 285A and the second semiconductor die 285B. In some embodiments, the cooling structure 445 directly contacts the base dielectric layer 110 on the exposed surface 175 of the stitching die 170.

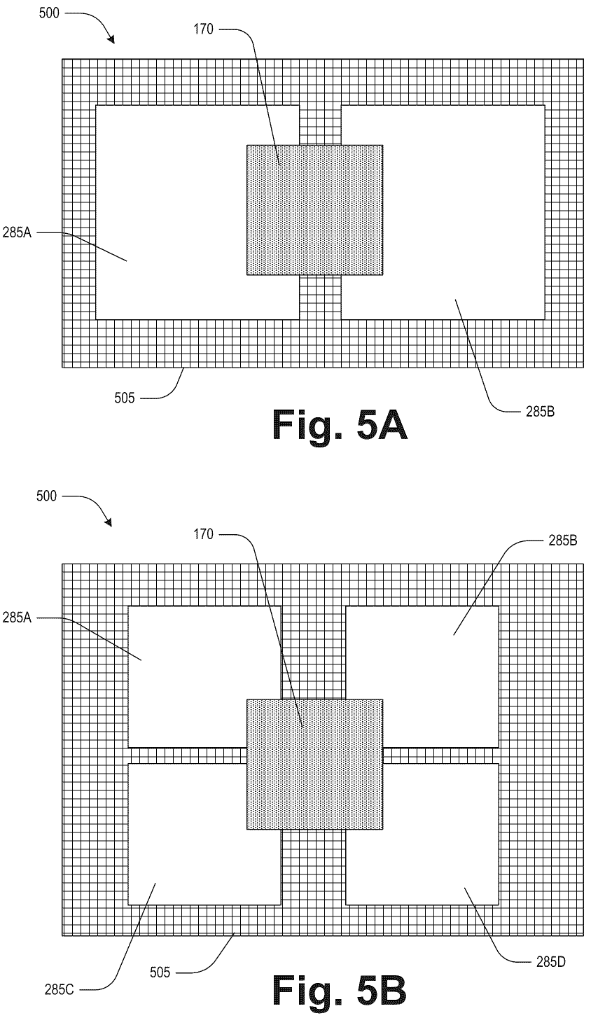

FIGS. 5A and 5B are top views of a semiconductor package 500, in accordance with some embodiments. Referring to FIG. 5A, the stitching die 170 interconnects two semiconductor dies 285A, 285B. The semiconductor dies 285A, 285B are mounted to a base 505, such as an underlying semiconductor die, a circuit board, an interposer, or some other base, as described above. Referring to FIG. 5B, the stitching die 170 interconnects four semiconductor dies 285A, 285B, 285C, 285D. The semiconductor dies 285A, 285B, 285C, 285D are mounted to the base 505. The number of semiconductor dies 285 interconnected by the stitching die 170 may vary.

The stitching die 170 facilitates communication between semiconductor dies 285 and die stacking to provide a combined processing complex that has a reduced footprint compared to a single semiconductor die with the same number of functional devices. The removal of the substrate layer 105 of the stitching die 170 allows the cooling structure 345, 445 to be positioned closer to the underlying semiconductor dies 285, thereby increasing cooling efficiency and potentially increasing processing performance.

In some embodiments, an apparatus includes a first semiconductor die including a first contact pad, a second semiconductor die including a second contact pad, a stitching die over the first semiconductor die and the second semiconductor die and including a third contact pad connected to the first contact pad and a fourth contact pad connected to the second contact pad. The apparatus also includes a cooling structure over the stitching die. The stitching die includes a first surface comprises a first dielectric material directly contacting the cooling structure.

In some embodiments, a method includes forming a stitching die by forming a dielectric layer over a first substrate layer, forming a first conductive structure in the dielectric layer and extending to a first surface of the dielectric layer, forming a second conductive structure in the dielectric layer and extending to the first surface of the dielectric layer, and removing the first substrate layer to expose a second surface of the dielectric layer. The stitching die is bonded to a first semiconductor die including a third conductive structure and to a second semiconductor die including a fourth conductive structure. The first conductive structure contacts the third conductive structure and the second conductive structure contacts the fourth conductive structure.

In some embodiments, a stitching die includes a dielectric layer having a first exposed surface and a second exposed surface, a first conductive structure embedded in the dielectric layer and extending to the first exposed surface without extending to the second exposed surface, and a second conductive structure embedded in the dielectric layer and extending to the first exposed surface without extending to the second exposed surface.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc., depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus, comprising:
a first semiconductor die comprising a first contact pad;
a second semiconductor die comprising a second contact pad;
a stitching die over the first semiconductor die and the second semiconductor die and comprising a third contact pad connected to the first contact pad and a fourth contact pad connected to the second contact pad; and
a cooling structure over the stitching die, wherein:
the stitching die comprises a first surface comprising a first dielectric material directly contacting the cooling structure.

2. The apparatus of claim 1, wherein:
the stitching die comprises a second surface opposite the first surface,
the second surface comprises a second dielectric material,
the third contact pad is embedded in the second dielectric material,
the first semiconductor die comprises a third surface comprising a third dielectric material,
the first contact pad is embedded in the third dielectric material, and
the second dielectric material is bonded to the third dielectric material.

3. The apparatus of claim 2, wherein the stitching die comprises:
a passivation layer under the second dielectric material, and
a conductive contact extending through the passivation layer and contacting the third contact pad.

4. The apparatus of claim 2, wherein the first semiconductor die comprises:
a substrate layer formed under the third dielectric material; and
a conductive contact extending through the substrate layer and contacting the first contact pad.

5. The apparatus of claim 2, wherein the first semiconductor die comprises:
a substrate layer;
an interlayer dielectric layer formed over the substrate layer; and
a conductive contact extending through the interlayer dielectric layer and contacting the first contact pad.

6. The apparatus of claim 1, wherein:
the first semiconductor die comprises a first seal ring; and
the stitching die comprises a second seal ring laterally offset from the first seal ring.

7. The apparatus of claim 1, comprising:
a molding material laterally between the first semiconductor die and the second semiconductor die and laterally adjacent the stitching die, wherein the cooling structure is over the molding material.

8. A method comprising:
forming a stitching die by:
forming a dielectric layer over a first substrate layer;
forming a first conductive structure in the dielectric layer and extending to a first surface of the dielectric layer;
forming a second conductive structure in the dielectric layer and extending to the first surface of the dielectric layer; and
removing the first substrate layer to expose a second surface of the dielectric layer; and
bonding the stitching die to a first semiconductor die comprising a third conductive structure and to a second semiconductor die comprising a fourth conductive structure, wherein the first conductive structure contacts the third conductive structure and the second conductive structure contacts the fourth conductive structure.

9. The method of claim 8, comprising:
forming a cooling structure over the second surface of the dielectric layer of the stitching die.

10. The method of claim 9, wherein forming the cooling structure comprises:
forming the cooling structure to directly contact the second surface of the dielectric layer of the stitching die.

11. The method of claim 8, comprising:
forming a first bonding layer over the first semiconductor die and the second semiconductor die;
forming a first contact pad in the first bonding layer contacting the third conductive structure; and
bonding a second bonding layer of the stitching die to the first bonding layer, wherein:
the dielectric layer comprises the second bonding layer.

12. The method of claim 11, wherein forming the dielectric layer of the stitching die comprises:
forming an interlayer dielectric layer;
forming a passivation layer over the interlayer dielectric layer; and
forming the second bonding layer over the passivation layer, wherein the first conductive structure extends through at least a portion of the interlayer dielectric layer, through the passivation layer, and through the second bonding layer.

13. The method of claim 8, comprising:
orienting the first semiconductor die in a back side up orientation prior to bonding the stitching die to the first semiconductor die, wherein:
the first semiconductor die comprises a second substrate layer, and
the third conductive structure extends through the substrate layer.

14. The method of claim 8, comprising:
orienting the first semiconductor die in a top side up orientation prior to bonding the stitching die to the first semiconductor die, wherein:
the first semiconductor die comprises a second substrate layer and an interlayer dielectric layer over the substrate layer, and
the third conductive structure extends through the interlayer dielectric layer.

15. The method of claim 8, comprising:
orienting the stitching die such that a seal ring in the stitching die is laterally offset from a seal ring of the first semiconductor die.

16. The method of claim 8, comprising:
forming a molding material laterally between the first semiconductor die and the second semiconductor die and laterally adjacent the stitching die; and
forming a cooling structure over the molding material to directly contact the second surface of the dielectric layer of the stitching die.

17. A stitching die, comprising:
a dielectric layer having a first exposed surface and a second exposed surface;
a first conductive structure embedded in the dielectric layer and extending to the first exposed surface without extending to the second exposed surface; and
a second conductive structure embedded in the dielectric layer and extending to the first exposed surface without extending to the second exposed surface.

18. The stitching die of claim 17, wherein the dielectric layer comprises:
an interlayer dielectric layer; and
a passivation layer over the interlayer dielectric layer.

19. The stitching die of claim 18, wherein the dielectric layer comprises a bonding layer over the passivation layer.

20. The stitching die of claim 17. comprising:
a seal ring in the dielectric layer.
